(19) United States
(12) Patent Application Publication
(10) Pub. No.: US 2005/0077908 A1
(43) Pub. Date: Apr. 14, 2005

(54) Continuity tester apparatus for wiring

(76) Inventor: Fred Fessenden, Hart, MI (US)

Correspondence Address: PRICE HENEVELD COOPER DEWITT & LITTON, LLP, 695 KENMOOR, S.E., P O BOX 2567, GRAND RAPIDS, MI, 49501, US

(21) Appl. No.: 10/685,949

(22) Filed: Oct. 13, 2003

(51) Int. Cl. H04B 3/46; G01R 31/02

(52) U.S. Cl. 324/543

(57) ABSTRACT

A kit is provided for making a continuity tester from an existing pliers tool and an existing continuity checker to check electrical continuity of a wire. The kit includes a first sleeve adapted to slip onto a free end of a first jaw of the pliers tool and which includes a protrusion that faces laterally, and a second sleeve adapted to slip onto a second jaw and which includes a pocket for holding the wire while the protrusion is piercing the wire. The first and second sleeves are tubular, and are held on by resilient tabs that frictionally engage the jaws. A connector adapted to frictionally engage the probe of the continuity checker is provided either on the first sleeve or on a third sleeve engagable with the first handle of the pliers tool. In one form, the kit is factory-installed as a permanent part of the pliers tool.

### BACKGROUND

The present invention relates to continuity testers for testing electrical continuity of wires, and more particularly relates to a continuity tester made for use with existing equipment commonly owned by repairmen, such as a continuity tester having an elongated probe with pointed end and with a pair of needle nose pliers.

Modern vehicles and crafts incorporate a large number of wires, which sometimes short out and require repair. A major part of the repair task is to check continuity to determine which wire is the problem and where the problem has occurred. The repair problem is compounded by the fact that the wires are often tucked into cramped corners and crevices where they are difficult to see and reach. Further, the testing equipment required for doing such testing is undesirably expensive, adding to the cost and frustrations of fixing the problem. Hence, repairmen need a simple continuity tester that can be manipulated and operated with one hand, and that is low-cost and durable.

There are several known continuity testers available. The “standard” continuity testers include a long pointed probe that is intended to pierce the insulated cover of a wire and contact the conductors inside. However, loose wires tend to spin and/or be difficult to trap against a support, such that it is often not an easy task to press the pointed probe against the wire with enough force to pierce the insulating cover. Further, if the wire conductor is electrically “hot” and the probe accidentally touches a metal ground or is extended through the wire conductor into a metal vehicle component, the wire conductor can ground out, causing a fuse to blow.

There are continuity testers of interest disclosed in several patents that are intended to cradle wires so that a test probe can pierce and test them. However, they typically are specialized separate tools that are quite expensive, and are useful only for this one single purpose. This is a problem because repairmen often already have “too many” tools . . . which means that their tools get lost and/or are difficult to find. Also, specialized tools are expensive, such that many repairmen cannot afford to buy them. Also, many existing specialized tools are bulky and difficult to take to jobs, and/or are heavy and/or difficult use.

Bohl U.S. Pat. No. 4,736,480 discloses a continuity tester of interest, where pliers are shown having a socket aligned with a center of a free end of one of its handles. Notably, the socket is adapted to receive a specifically sized plug, such that it is only usable with a specific continuity tester. For example, the plug has a very specific diameter and length, and the insulated casing on the plug must also be a very specific length and shape because it is adapted to seal against the end of the plug-receiving cavity on the tool. Not only is it NOT designed to engage different sizes of plugs, but also the plug sticks out a long way from the handle since a full length of the continuity tester extends from an end of the handle. This can be problematic when trying to manipulate the tool in tight quarters.

Thus, a tool and/or kit having the aforementioned advantages and solving the aforementioned problems is desired.

### SUMMARY OF THE PRESENT INVENTION

In one aspect of the present invention, a tester for checking electrical continuity of a wire is provided, the tester being adapted for use with an existing continuity checker having a rod-type pointed probe. The tester includes a pliers tool having first and second levers pivoted together, and defining first and second jaws, respectively, and also first and second handles, respectively. The first jaw includes a protrusion adapted to pierce insulation on the wire and make contact with an electrical conductor inside the wire, and the second jaw includes a mating pocket adapted to receive and hold the wire while the protrusion is piercing the wire. A universal connector is attached to a side of the first lever and is electrically coupled to the protrusion. The universal connector defines an elongated cavity adapted to loosely receive the probe of the existing continuity checker so that different probes of unknown diameter and length can be engaged. The universal connector includes a retainer spring adapted to slidingly engage and bias the probe toward a side of the cavity, with at least one of the first lever and the retainer spring being in electrical contact with the probe. The retainer spring is adapted to frictionally engage the probe in a lateral direction to positively retain the probe within the cavity so that the continuity tester and the pliers tool can be manipulated as a unit for one-handed operation by a repairman. By this arrangement, the tester is adapted for secure attachment to the existing continuity checker and is adapted for one-handed manipulation and use by the repairman to test continuity of the wire.

In another aspect of the present invention, a kit is provided for making a continuity tester apparatus from a pliers tool to check electrical continuity of a wire, the tester apparatus being adapted for use with an existing continuity tester having a probe. The pliers tool provided has first and second levers pivoted together, the first and second levers defining first and second jaws, and also first and second handles, respectively, with the first lever being conductive so that the first jaw and first handle are electrically connected. The kit includes a first member adapted to engage the first jaw, including a protrusion for piercing insulation on the wire and for making contact with an electrical conductor inside the wire, and further includes a second member adapted to engage the second jaw, including a pocket for receiving and holding the wire while the protrusion is piercing the wire. A universal connector defines an elongated cavity adapted to loosely receive the probe. The universal connector further includes a retainer spring adapted to slidingly engage and bias the probe toward a side of the cavity, with the spring being strong enough to frictionally engage the probe in a lateral direction to retain the probe within the cavity and join the continuity tester to the pliers tool for manipulation therewith as a unit for one-handed operation by a repairman.

In another aspect of the present invention, an apparatus for making a continuity tester from a pliers tool and a continuity checker to check electrical continuity of a wire includes first and second sleeves and a connector. The first sleeve is adapted to telescopingly slip onto a free end of the first jaw, and includes a pointed protrusion that faces laterally for piercing insulation on the wire and for making contact with an electrical conductor inside the wire, and still further includes a resilient first retainer adapted to snappingly frictionally engage the first jaw. The second sleeve is adapted to telescopingly slip onto the second jaw, and includes a pocket facing laterally for receiving and holding the wire while the protrusion is piercing the wire, and further includes a resilient second retainer adapted to snappingly frictionally engage the second jaw. The connector is provided for electrically connecting the pointed protrusion of the first sleeve and is adapted to operably engage the continuity checker for checking a continuity of the electrical conductor inside the wire.

These and other aspects, objects, and features of the present invention will be understood and appreciated by those skilled in the art upon studying the following specification, claims, and appended drawings.

### BRIEF DESCRIPTION OF DRAWINGS

FIG. 1 is a side view of an apparatus embodying the present invention, including first and second sleeves telescoped onto jaws of an existing pliers tool and with an existing continuity tester engaged with a universal connector on the first sleeve;

FIG. 1A is an enlarged view of the circled area in FIG. 1;

FIG. 2 is an exploded view of FIG. 1;

FIG. 3 is a side view of a modified apparatus, which includes a third sleeve adapted to telescopingly engage a handle on the pliers tool; and

FIG. 4 is a side view of a second modified apparatus, which includes a pliers tool adapted with features of the present invention.

### DETAILED DESCRIPTION OF PREFERRED EMBODIMENTS

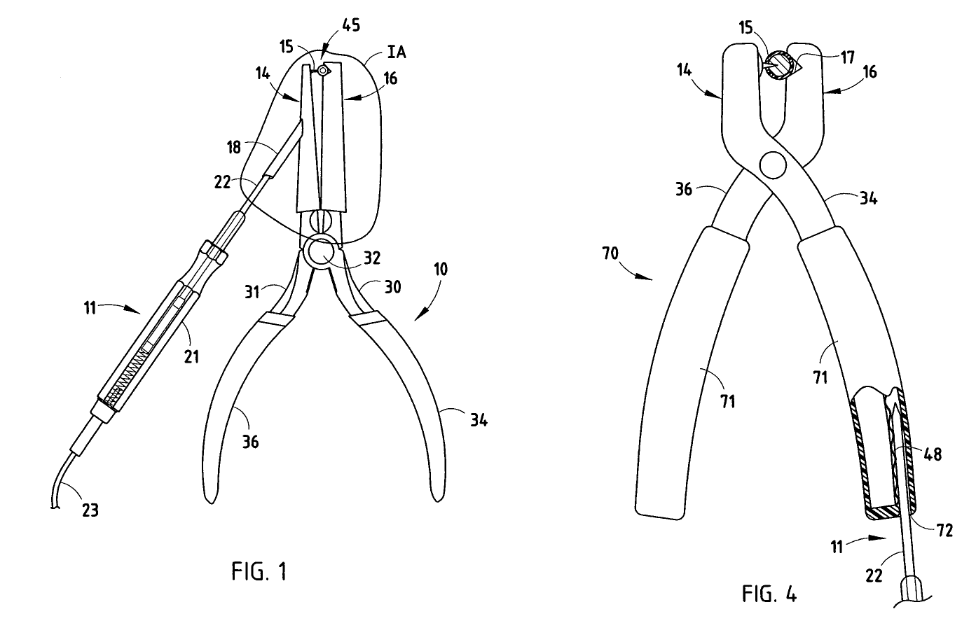

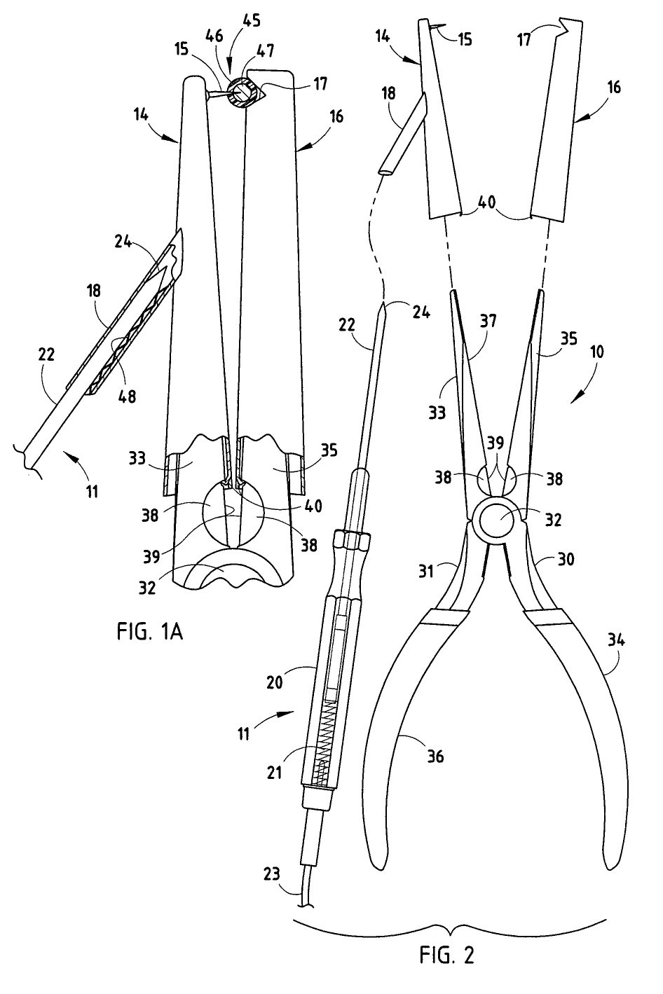

A kit (FIGS. 1-2) is provided for making a continuity tester from an existing pliers tool 10 and an existing continuity tester 11 (also called a “continuity checker” herein) to check electrical continuity of a wire 45. The kit includes a first sleeve 14 adapted to slip onto a free end of the first jaw and which includes a protrusion 15 that faces laterally, and a second sleeve 16 adapted to slip onto the second jaw and which includes a pocket 17 for holding the wire 45 while the protrusion is piercing the insulating cover 46 of the wire 45 and making contact with the conductor 47 inside the wire 45. The first and second sleeves 14 and 16 are tubular, and are held on by resilient tabs that frictionally engage the jaws. A tubular universal connector 18 adapted to receive and frictionally engage the probe of the continuity checker is provided either on the first sleeve 14 (or alternatively is provided on a third sleeve engageable with the first handle of the pliers tool 10 (see FIG. 4).

The existing continuity tester 11 (FIG. 2) includes an insulated handle 20 having a light 21 therein to show when electrical power is communicated to the tester 11. An elongated probe 22 having a length about equal to the handle 20 is provided, and is electrically connected to the light 21 and to a ground wire 23. The ground wire 23 can include an alligator clip or the like for snap attachment to an electrical ground. The probe 22 includes a pointed tip 24. During use, the ground wire 23 is grounded, and then the probe 22 is pressed against a wire with sufficient force to pierce the insulating cover of the wire and contact its inner conductor(s). As discussed above, this is not an easy task, since the wire spins or moves, or the pointed tip 24 extends into electrical contact with another grounded vehicle component, causing problems. It is noted that probes 22 on existing continuity testers 11 may vary in diameter and length, such that it is not possible to engage them with a single diameter socket of predetermined length.

The illustrated existing pliers tool 10 (FIG. 2) is commonly referred to as needle nose pliers. The pliers tool 10 includes first and second levers 30 and 31 pivoted at pivot 32. The first lever 30 includes a jaw 33 at one end, and a handle 34 at the other end, and the second lever 31 includes a jaw 35 at one end and a handle 36 at its other end. The illustrated jaws 33 and 35 are elongated, and include a rounded back side and a flat side with teeth 37, and further include a notch 38 with a sharp ridge 39 such as for cutting wires. The jaws 33 and 35 are fairly standard in length and shape, and made of a durable conductive metal.

The first sleeve 14 (FIG. 2) is tubular, made of a conductive metal, and shaped to slip telescopingly onto the jaw 33. Specifically, the sleeve 14 has a tapered shape, with a flat side for matingly (non-rotatably) engaging the flat surface with teeth 37, and further includes a resilient tab 40 for snappingly (removably) engaging the notch 38 at an end of the teeth 37 when fully installed. The tab 40 can be made bendable for a more secure and permanent attachment if desired. The second sleeve 16 is similarly shaped, such that it does not require a repeated discussion. The first sleeve 14 includes a protrusion 15 extending laterally from its flat side, such as the illustrated pointed protrusion, for piercing the insulating cover 46 of the wire 43, and for making electrical contact with the conductor 47 in the wire 45. The second sleeve 16 includes the mating groove-like pocket 17 which is positioned to hold the wire 45 as the protrusion 15 is moved to piercingly engage the wire 45.

The universal connector 18 as illustrated in FIG. 2 is metal and is welded or otherwise fixed to the first sleeve 14 so that it is in electrical contact therewith. The universal connector 18 is also tubular and shaped to receive a largest one of the probes 22 of the potential existing continuity testers 11 that may be used with the present apparatus 10. An elongated spring 48 is attached inside the cavity of connector 18, and includes a stiff resilient band of material forming a plurality of undulations that are adapted to engage and contact the probe 22 at multiple locations so that the probe 22, once inserted, is securely frictionally held and also is in secure electrical contact therewith. This allows the pliers tool 10 and continuity tester 11 to be manipulated as a unit with one hand of the repairman. Notably, the probe 22 on standard continuity testers is usually quite long. Nonetheless, the universal connector 18 is positioned on a side of the jaw 14, in a position where a good amount of its length simply runs parallel the handle 14 of the pliers 10. Thus, the lengths do not cumulatively “add” to each other. This also has the combined apparatus 10/11 closer to the repairman's hand, such that it is more balanced and easier to use. It is also contemplated that different components can be used, such as one for securely frictionally engaging the probe 22 and another component for making electrical contact with the probe. Where the sleeve 14 is made of metal, both the sleeve 14 and the spring 48 are in electrical contact with the probe 22.

In use, the sleeves 14 and 16 are attached to a pair of existing needle nose pliers 10, and the existing continuity tester 11 is inserted into the universal connector 18. The continuity tester 11 is grounded, and the apparatus used as a unit to test for circuit/wire continuity.

It is contemplated that a number of modifications and alterations can be made to the kit and pliers tool. Two such modifications are shown, for the purpose of illustrating the flexibility of the present invention, but it is specifically contemplated that additional variations can be made, as will be recognized by persons of ordinary skill upon reading the present disclosure. The modifications are described using the same identification numbers. This is done to reduce redundant discussion and not for another purpose.

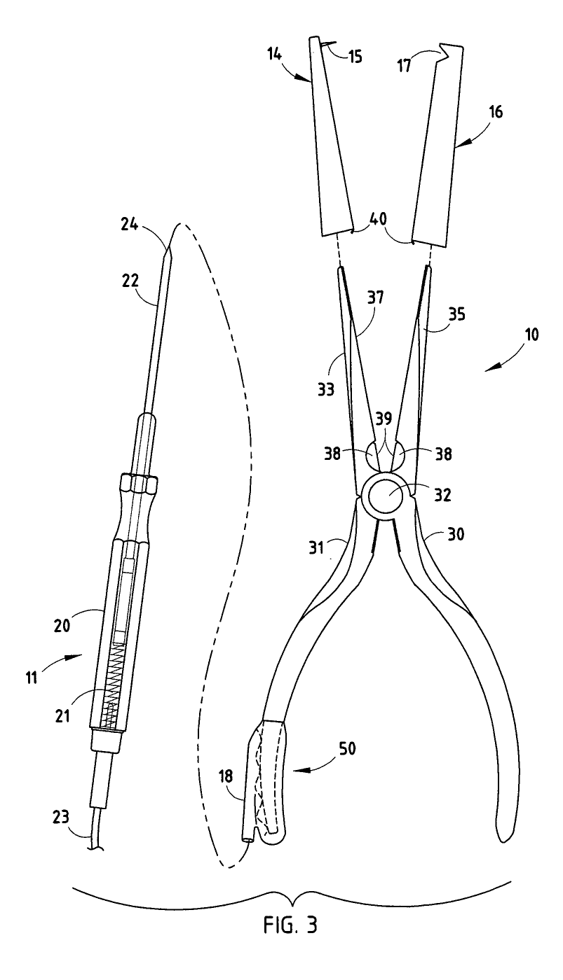

In a modified kit, a third sleeve 50 is provided for engaging the handle 34, and the universal connector 18 is mounted on the third sleeve 50 (FIG. 3). Notably, where the handle 34 has a rubber or insulating cover on it, the sleeve 50 must have a tab or other piercing electrical contact to make good contact with the metal of the handle 34.

In a modified tool, the features and function of the kit is incorporated permanently into a pliers tool 70. Pliers tool 70 includes pivoted levers similar to the levers 14 and 16 of tool 10. In the illustrated tool, a resilient cover 71 surrounds and insulates the handle 34. As shown, the cover 71 includes an aperture 72 so that the probe 22 can be extended into the aperture 72 along an outside surface of the handle 34. The spring 48 is positioned to oppose the cover 71 in a manner that causes the cover 71 (and the spring 48) to opposingly frictionally engage the probe 22. (This takes advantage of the friction properties of the rubber, and further lets the tool manufacturer use existing parts.) Due to the side position of the probe 22, there is an “overlapped” condition so that the full lengths of the continuity tester 11 and the pliers tool 70 do not cumulatively combine. An added benefit is that a center of gravity of the combined apparatus 70/11 is closer to the repairman's hand, such that it is more balanced and easier to use.

It is to be understood that variations and modifications can be made on the aforementioned structure without departing from the concepts of the present invention, and further it is to be understood that such concepts are intended to be covered by the following claims unless these claims by their language expressly state otherwise.

1. A tester for checking electrical continuity of a wire, the tester being adapted for use with an existing continuity checker having a rod-type pointed probe, the tester comprising:
a pliers tool including first and second levers pivoted together, and defining first and second jaws, respectively, and also first and second handles, respectively; the first jaw including a protrusion adapted to pierce insulation on the wire and make contact with an electrical conductor inside the wire, and the second jaw including a mating pocket adapted to receive and hold the wire while the protrusion is piercing the wire; and
a universal connector attached to a side of the first lever and electrically coupled to the protrusion, the universal connector defining an elongated cavity adapted to loosely receive the probe of the existing continuity checker so that different probes of unknown diameter and length can be engaged, and the universal connector including a retainer spring adapted to slidingly engage and bias the probe toward a side of the cavity, with at least one of the first lever and the retainer spring being in electrical contact with the probe, the retainer spring being adapted to frictionally engage the probe in a lateral direction to positively retain the probe within the cavity so that the continuity tester and the pliers tool can be manipulated as a unit for one-handed operation by a repairman; whereby the tester is adapted for secure attachment to the existing continuity checker and is adapted for one-handed manipulation and use by the repairman to test continuity of the wire.

2. The tester defined in claim 1, wherein the first lever is made of a conductive material so that the first jaw and first handle are electrically connected.

3. The tester defined in claim 1, wherein the universal connector is attached to a side surface of the first handle.

4. The tester defined in claim 3, wherein the universal connector is positioned separate from the first jaw and makes electrical contact with the protrusion through conducting material of the first lever.

5. The tester defined in claim 1, including a first sleeve that telescopingly engages the first jaw and includes the protrusion.

6. The tester defined in claim 5, wherein the universal connector is attached to and extends from a side of the first sleeve.

7. The tester defined in claim 5, wherein the first sleeve is tubular and adapted to telescopingly engage the first jaw and frictionally engage and be retained thereon.

8. The tester defined in claim 7, wherein the first sleeve includes a releasable retainer for retaining the first sleeve on the first jaw.

9. The tester defined in claim 7, wherein the first sleeve includes a tab that snap-attaches to and frictionally engages the first jaw.

10. The tester defined in claim 9, wherein the retainer includes a tab adapted to frictionally engage a notch on the first jaw at a rear of teeth located on a flat surface on the jaw.

11. The tester defined in claim 1, including a first sleeve that telescopingly engages a side of the first handle and includes the universal connector in a position beside a handle where the universal connector is adapted to minimize a combined length of the pliers tool and an existing continuity tester engaging the universal connector.

12. A kit for making a continuity tester apparatus from a pliers tool to check electrical continuity of a wire, the tester apparatus being adapted for use with an existing continuity tester having a probe, the pliers tool having first and second levers pivoted together, the first and second levers defining first and second jaws, and also first and second handles, respectively, with the first lever being conductive so that the first jaw and first handle are electrically connected, the kit comprising:
a first member adapted to engage the first jaw, including a protrusion for piercing insulation on the wire and for making contact with an electrical conductor inside the wire;
a second member adapted to engage the second jaw, including a pocket for receiving and holding the wire while the protrusion is piercing the wire; and
a universal connector defining an elongated cavity adapted to loosely receive the probe, the universal connector including a retainer spring adapted to slidingly engage and bias the probe toward a side of the cavity, with the spring being strong enough to frictionally engage the probe in a lateral direction to retain the probe within the cavity and join the continuity tester to the pliers tool for manipulation therewith as a unit for one-handed operation by a repairman.

13. The kit defined in claim 12, wherein the first member includes opposing portions that are adapted to frictionally engage the first jaw.

14. The kit defined in claim 13, wherein the first and second members each are constructed to telescopingly engage the first jaw and the second jaw, respectively.

15. The kit defined claim 12, wherein the first and second members are tubular and include a flat side to non-rotatably engage the first and second jaws.

16. The kit defined in claim 12, wherein the first and second members include a tab for frictionally and removably engaging the first and second jaws, respectively.

17. The kit defined in claim 12, wherein the universal connector is formed as part of and integrally attached to the first member.

18. The kit defined in claim 17, wherein the universal connector comprises a tubular member extending laterally from a side of the first member.

19. The kit defined in claim 12, including a third member, the first member, second member, and third member being tubular and shaped to releasably engage and make electrical contact with the first jaw, the second jaw, and handle, the universal connector being on the third member.

20. The kit defined in claim 12, wherein the universal connector includes a retaining spring electrically connected to the protrusion on the first member.

21. An apparatus for making a continuity tester from a pliers tool and a continuity checker to check electrical continuity of a wire, comprising:
a first sleeve adapted to telescopingly slip onto a free end of the first jaw, the first sleeve including a pointed protrusion that faces laterally and that is adapted to pierce insulation on the wire and make contact with an electrical conductor inside the wire, and including a resilient first retainer adapted to snappingly frictionally engage the first jaw; and
a second sleeve adapted to telescopingly slip onto the second jaw, including a pocket facing laterally and that is adapted to receive and hold the wire while the protrusion is piercing the wire, and including a resilient second retainer adapted to snappingly frictionally engage the second jaw; and
a connector for electrically connecting to the pointed protrusion and that is adapted to operably engage a continuity tester for checking a continuity of the electrical conductor inside the wire.

22. The apparatus defined in claim 21, wherein the connector is attached to the second sleeve and includes a universal connector adapted to be electrically connected to the pointed protrusion, the connector defining an elongated cavity that is over-sized and adapted to loosely receive the probe.

23. The apparatus defined in claim 21, including a third sleeve adapted to slip onto a free end of the first handle, the third sleeve including the connector and being adapted to be electrically connected to the protrusion.

24. The apparatus defined in claim 21, wherein the connector includes a retainer spring adapted to slidingly engage and bias the probe toward a side of the cavity, with the retainer spring being electrically in contact with the probe and with the retainer spring being strong enough to frictionally engage the probe in a lateral direction to retain the probe within the cavity and join the continuity tester to the pliers tool for manipulation therewith as a unit for one-handed operation by a repairman.
